(19) United States
(12) Patent Application Publication
(10) Pub. No.: US 2015/0021621 A1
(43) Pub. Date: Jan. 22, 2015

(54) SELF-ALIGNED GATE BURIED CHANNEL FIELD EFFECT TRANSISTOR

(71) Applicant: RamGoss, Inc., Boston, MA (US)

(72) Inventors: Bunmi T. ADEKORE, Medford, MA (US); Hugues MARCHAND, Somerville, MA (US)

(21) Appl. No.: 14/336,654

(22) Filed: Jul. 21, 2014

Related U.S. Application Data
(60) Provisional application No. 61/856,384, filed on Jul. 19, 2013.

(51) Int. Cl. H01L 29/78; H01L 29/20; H01L 29/66; H01L 29/24

(52) U.S. Cl. CPC H01L 29/7827; H01L 29/24; H01L 29/2003; H01L 29/66969; H01L 29/66666
USPC 257/76; 438/268

(57) ABSTRACT

This disclosure provides a transistor device formed on a wide band gap substrate. The transistor device includes a channel layer and a gate structure physically coupled to the channel layer. The gate structure can be formed on the channel layer using an epitaxial process instead of a lithographic process, thereby providing a mechanism to build small semiconductor features that are smaller than a resolution of the state-of-the-art lithographic process and reducing the amount of impurities between the channel layer and the gate structure.

### CROSS REFERENCE TO RELATED APPLICATIONS

This application claims benefit of the earlier filing date, under 35 U.S.C. §119(e), of U.S. Provisional Application No. 61/856,384, filed on Jul. 19, 2013, entitled “SELF-ALIGNED GATE BURIED CHANNEL FIELD EFFECT TRANSISTOR”, which is herein incorporated by reference in its entirety.

### FIELD OF INVENTION

The present disclosure relates generally to metal junction and metal insulator field effect transistors and methods of making the same, and more specifically to a vertical self-aligned gate buried channel field effect transistor (SAGBC-FET) for high power applications (e.g., with voltage and current ratings about 600V and at least about 1 A respectively.)

### BACKGROUND

A vertical junction semiconductor field effect transistor (VJFET) is a unique class of a three-terminal power transistor device. A vertical junction semiconductor field effect transistor (VJFET) can include source, drain, and gate terminals, where the electric field sustained between the source terminal and the drain terminal is distributed vertically.

A VJFET is typically manufactured using silicon and silicon carbide—based semiconductor materials. The advantage of using silicon and silicon carbide—based semiconductor materials includes cost-efficacy and a high performance functionality around a low defect interface between silicon or silicon carbide and silicon dioxide and/or other “high-K” dielectric materials, such as hafnium oxide, which are materials suspended between the semiconductor and the gate terminal and employed to achieve the transistor field effect.

However, silicon based VJFETs have fundamental limits due to a low critical field of silicon, the electric field beyond which silicon breaks down and losses its semiconductor properties. Such a low critical field of silicon can be attributed to relatively low band gap energy of 1.14 eV; its low switching frequency of below 100 kHz; its high on-resistance of above 200 mΩ-cm⁻²; and its low operating temperatures of about 150° C.

Silicon carbide (SiC) based devices have extended the functionality of silicon-based VJFETs to higher electric fields and thus higher operating voltages of up to 10 kV. Such an extension of functionality was feasible due to SiC's higher band gap energy of 3.0 eV, and thus a higher critical field; its higher switching frequencies; its desirable, lower on-resistances; and its higher operating temperatures of about 230° C. However, SiC materials are expensive, about 10 to 100 times the cost of silicon. Therefore, the broad market adoption of SiC based devices has been limited.

### SUMMARY

The present disclosure relates to a vertical self-aligned gate buried channel field effect transistor (SAGBC-FET.) In one aspect, the SAGBC-FET device comprises a substrate of a wide band gap semiconductor material such as SiC, Gallium Nitride (GaN) or Zinc Oxide (ZnO)-based materials, and a structure disposed on a first side of the substrate, the structure comprising a plurality of semiconductor layers and the semiconductor layers comprising of a plurality of AlₓGa₁₋ₓN and/or ZnₓMg₁₋ₓO materials and metal and or conducting semiconductor electrodes supported on the first and second side of substrate.

In one aspect, the SAGBC-FET device comprises a substrate of a wide band gap semiconductor material such as SiC or GaN or ZnO-based materials which is n-type, and a structure disposed on a first side of the substrate, the structure comprising a plurality of semiconductor layers and the semiconductor layers comprising of a plurality of AlₓGa₁₋ₓN and/or ZnₓMg₁₋ₓO materials comprising of n-type and/or p-type species and wherein the n-type or p-type species may be introduced by one or a plurality of doping techniques including ion-implantation, gas-phase incorporation, solution incorporation and diffusion and with metal and or conducting semiconductor electrodes supported on the first and second side of substrate.

In one aspect, a vertical transistor is provided including a substrate; a first semiconducting layer disposed above a first side of the substrate; a second semiconducting layer disposed above the first semiconducting layer, wherein the second semiconducting layer comprises a trench that exposes the first semiconducting layer; a channel layer disposed within the trench, wherein the channel layer is in direct contact with the first semiconducting layer exposed by the trench; a gate structure disposed above the channel layer, wherein the gate structure is partially disposed within the trench, and a width of a depletion region between the channel layer and the first semiconducting layer is controllable by a voltage applied to the gate structure; and a source electrode, a gate electrode coupled to the gate structure, and a drain electrode.

In one or more embodiments, the substrate includes a ZnO-based material.

In one or more embodiments, the channel layer includes a first dopant having an opposite polarity compared to that of a second dopant in the second semiconducting layer.

In any preceding embodiment, a thickness of the channel layer is predetermined to control a maximum current that can be provided by the transistor.

In any preceding embodiment, the channel layer and the gate structure are formed in two consecutive, identical epitaxial process steps.

In any preceding embodiment, the epitaxial process includes one of a metal-organic chemical vapor deposition (MOCVD) process, a molecular beam epitaxy (MBE) process, an atomic layer deposition (ALD) process, a hydride vapor phase epitaxy (HVPE) process, a chemical vapor transport (CVT) process, or a liquid phase epitaxy (LPE) process.

In any preceding embodiment, a pitch of the gate structure is determined by a thickness of the channel layer.

In any preceding embodiment, the pitch of the gate structure is further determined by a width of the trench in the second semiconducting layer.

In any preceding embodiment, a pitch of the gate structure is smaller than a minimum feature size of a lithographic process used to form the trench in the second semiconducting layer.

In any preceding embodiment, the first semiconducting layer is AlₓGa₁₋ₓN and/or ZnₓMg₁₋ₓO materials, wherein 0<x<1.

In any preceding embodiment, a thickness of the first semiconducting layer is within a range of about 3 μm and about 300 μm.

In any preceding embodiment, the vertical transistor further includes a field gate electrically coupled to the second semiconducting layer, wherein a width of a depletion region between the channel layer and the second semiconducting layer is designed to be controlled by a voltage applied to the field gate.

In any preceding embodiment, the source electrode and the field gate are electrically coupled, thereby forming a body diode in series with the vertical transistor.

In any preceding embodiment, the gate structure comprises a semiconducting material having an identical polarity as that of the first semiconducting layer and an opposite polarity as that of the second semiconducting layer.

In any preceding embodiment, the gate structure is a dielectric.

In any preceding embodiment, the vertical transistor further includes a recess coupled to the channel layer, forming a body diode between the recess and the second semiconducting layer.

In any preceding embodiment, the substrate comprises a material having a crystal orientation selected from the group consisting of (000±1) c-plane polar materials, (10±10) m-plane non-polar materials, (11±20) a-plane non-polar materials, and (10-1±1), (20-2±1), (10-1±2), (11-2±1), (11-2±2) semipolar materials.

In another aspect, a method of providing a transistor includes providing a substrate; providing a first semiconducting layer on a first side of the substrate; depositing a second semiconducting layer on the first semiconducting layer; providing a trench in the second semiconducting layer to expose a portion of the first semiconducting layer; depositing a channel layer on the second semiconducting layer and the exposed portion of the first semiconducting layer, thereby providing a direct contact between the channel layer and the first semiconducting layer in the trench; depositing a gate structure on the channel layer, wherein a portion of the gate structure is formed in the trench; and providing a source electrode, a gate electrode coupled to the gate structure, and a drain electrode.

In one embodiment, the method further includes providing a buffer layer between the first semiconducting layer and the substrate to facilitate a formation of the first semiconducting layer.

In one embodiment, the method further includes controlling an amount of time for depositing a semiconducting material for the channel layer, thereby controlling a thickness of the channel layer.

In one embodiment, the method further includes controlling a concentration of a semiconducting material for the channel layer during the deposition of the channel layer to control a thickness of the channel layer.

The method according to any preceding embodiment, wherein providing the trench in the second semiconducting layer comprises using a lithographic technique to form the trench in the second semiconducting layer.

In any preceding embodiment, the channel layer and the gate structure are deposited in two consecutive, identical epitaxial process steps.

In any preceding embodiment, the epitaxial process comprises one of a metal-organic chemical vapor deposition (MOCVD) process, a molecular beam epitaxy (MBE) process, an atomic layer deposition (ALD) process, a hydride vapor phase epitaxy (HVPE) process, a chemical vapor transport (CVT) process, or a liquid phase epitaxy (LPE) process.

In any preceding embodiment, the channel layer comprises a first dopant having an opposite polarity compared to that of a second dopant in the second semiconducting layer.

In any preceding embodiment, a thickness of the first semiconducting layer is within a range of about 3 μm and about 300 μm.

Other aspects, embodiments and features of the invention will become apparent from the following detailed description of the invention when considered in conjunction with the accompanying drawings. The accompanying figures are schematic and are not intended to be drawn to scale. In the figures, each identical, or substantially similar component that is illustrated in various figures is represented by a single numeral or notation. For purposes of clarity, not every component is labeled in every figure. Nor is every component of each embodiment of the invention shown where illustration is not necessary to allow those of ordinary skill in the art to understand the invention. All patent applications and patents incorporated herein by reference are incorporated by reference in their entirety. In case of conflict, the present specification, including definitions, will control.

### BRIEF DESCRIPTION OF DRAWINGS

FIG. 1 illustrates a structure of a self-aligned gate buried channel field effect transistor (SAGBC-FET) in accordance with some embodiments.

FIG. 2 illustrates a SAGBC-FET in series with a body-diode in accordance with some embodiments.

FIG. 3 shows a cross-sectional view of a SAGBC-FET having a dielectric gate structure in accordance with some embodiments.

FIG. 4 shows a cross-sectional view of a SAGBC-FET having recesses in accordance with some embodiments.

FIG. 5 shows a cross-sectional view of a SAGBC-FET having recesses and a dielectric gate structure in accordance with some embodiments.

### DETAILED DESCRIPTION

Reference now will be made in detail to the presently preferred embodiments of the invention. Such embodiments are provided by way of explanation of the invention, which is not intended to be limited thereto. In fact, those of ordinary skill in the art can appreciate upon reading the present specification and viewing the present drawings that various modifications and variations can be made.

Before explaining at least one embodiment of the invention in detail, it is to be understood that the invention is not limited in its application to the details of construction and to the arrangements of the components set forth in the following description or illustrated in the drawings. The invention is capable of other embodiments and of being practiced and carried out in various ways. Also, it is to be understood that the phraseology and terminology employed herein are for the purpose of description and should not be regarded as limiting. Numerous embodiments are described in this patent application, and are presented for illustrative purposes only. The described embodiments are not intended to be limiting in any sense. The invention is widely applicable to numerous embodiments, as is readily apparent from the disclosure herein. Those skilled in the art will recognize that the present invention can be practiced with various modifications and alterations. Although particular features of the present invention can be described with reference to one or more particular embodiments or figures, it should be understood that such features are not limited to usage in the one or more particular embodiments or figures with reference to which they are described.

As such, those skilled in the art will appreciate that the conception, upon which this disclosure is based, can readily be utilized as a basis for the designing of other structures, methods and systems for carrying out the several purposes of the present invention. It is important, therefore, that the invention be regarded as including equivalent constructions to those described herein insofar as they do not depart from the spirit and scope of the present invention.

For example, the specific sequence of the described process can be altered so that certain processes are conducted in parallel or independent, with other processes, to the extent that the processes are not dependent upon each other. Thus, the specific order of steps described herein is not to be considered implying a specific sequence of steps to perform the process. Other alterations or modifications of the above processes are also contemplated. For example, further insubstantial approximations of the process and/or algorithms are also considered within the scope of the processes described herein.

In addition, features illustrated or described as part of one embodiment can be used on other embodiments to yield a still further embodiment. Additionally, certain features can be interchanged with similar devices or features not mentioned yet which perform the same or similar functions. It is therefore intended that such modifications and variations are included within the totality of the present invention.

Conventionally, a device fabrication system can form features of a transistor device on a wafer using a photolithographic process. In particular, the device fabrication system can use the photolithographic process to create a negative image of desired features on a wafer using a photoresist layer and an optical mask. For example, the device fabrication system can deposit a layer of a semiconducting material onto a wafer, and the system can also deposit a layer of photoresist onto the layer of the semiconducting material. Subsequently, the device fabrication system can cover the wafer with an optical mask and expose the mask-covered wafer to light. The optical mask is configured to pass the light only in predetermined regions, in accordance with the desired features of the transistor device. Therefore, once the device fabrication system shines the light onto the mask-covered wafer, only the predetermined regions of the photoresist layer would be exposed to the light. The device fabrication system can remove the light-exposed regions of the photoresist layer from the wafer, thereby forming a negative image of the desired features on the photoresist layer. The negative image of the features on the photoresist layer also exposes the underlying semiconductor layer.

Subsequently, the device fabrication system can etch the exposed portions of the semiconductor layer using an etching process. This way, the device fabrication system can form a negative image of the desired features on the semiconducting layer as well as the photoresist layer. Then the device fabrication system can remove the photoresist layer, which completes the patterning of the desired features (or a negative image of the desired features) on the semiconductor layer. The device fabrication system can repeat the deposition of a semiconductor layer and the partial etching of the deposited semiconductor layer in order to form various features of a transistor device on multiple semiconductor layers.

Because features of a conventional power transistor device are defined using a photolithographic process, the minimum size of the features depends on a resolution of the device fabrication system, in particular a resolution of the photolithographic technique used by the device fabrication system. For example, a minimum channel length of a transistor in a state-of-the-art device fabrication system is at least 22 nm. Such a lack of flexibility over a minimum feature size can limit a potential of a transistor device in various applications.

An additional disadvantage to using a photographic process is an introduction of impurities. The photolithographic process can introduce undesired impurities at an interface of two layers formed on a wafer. For example, once the device fabrication system deposits a first layer on a wafer, the device fabrication system can pattern the first layer using a lithographic process. Unfortunately, during the lithographic process, the device fabrication system can introduce various types of impurities at the top of the first layer. Even when the device fabrication system subsequently deposits a second layer onto the patterned first layer, the impurities can remain at the interface of the first layer and the second layer. These impurities are undesirable because the impurities can degrade a performance of a transistor device formed using the first layer and the second layer.

These disadvantages of a conventional power transistor devices can be addressed using a vertical self-aligned gate buried channel field effect transistor (SAGBC-FET) devices and methods for providing the SAGBC-FET. The SAGBC-FET does not require a use of a photolithographic process for defining a channel region or a gate region. Instead, the channel region and the gate region of the SAGBC-FET can be formed using an epitaxial process—a process for depositing a layer of material onto a wafer. Therefore, a width of a channel region in the SAGBC-FET or a width of a gate region is not constrained by a resolution of the photolithographic process, but is constrained by a precision of the epitaxial process, which can be very high, and/or a relative thickness of the channel region, which can also be controlled accurately.

Furthermore, because the channel region and the gate region of the SAGBC-FET do not require a use of a photolithographic process, the amount of impurities at an interface between the channel region and the gate region can be substantially reduced. The reduced amount of impurities at the interface between the channel region and the gate region can reduce a leakage current of the SAGBC-FET, thereby improving an on-off switching characteristic of the SAGBC-FET.

In general, a SAGBC-FET can include a substrate, one or more epitaxial layers deposited on the substrate, a planar or recessed channel layer deposited on the epitaxial layers, a gate region deposited on the channel layer, and electrodes coupled to the gate region and the channel layer for controlling an on-off state of the SAGBC-FET. A voltage applied to a gate electrode (e.g., an electrode coupled to the gate region) can control a size of a depletion region in the channel layer, thereby controlling the amount of current flowing through the channel layer. The SAGBC-FET can include a trench that allows the channel layer to come in contact with the one or more epitaxial layers deposited on the substrate. Therefore, the channel layer is buried within the SAGBC-FET device. The trench can also accommodate a gate region. Therefore, the gate region is self-aligned with a portion of the channel layer that is in contact with the one or more epitaxial layers deposited on the substrate. This use of a trench obviates a need to use a lithographic technique to align a gate region with respect to a channel region.

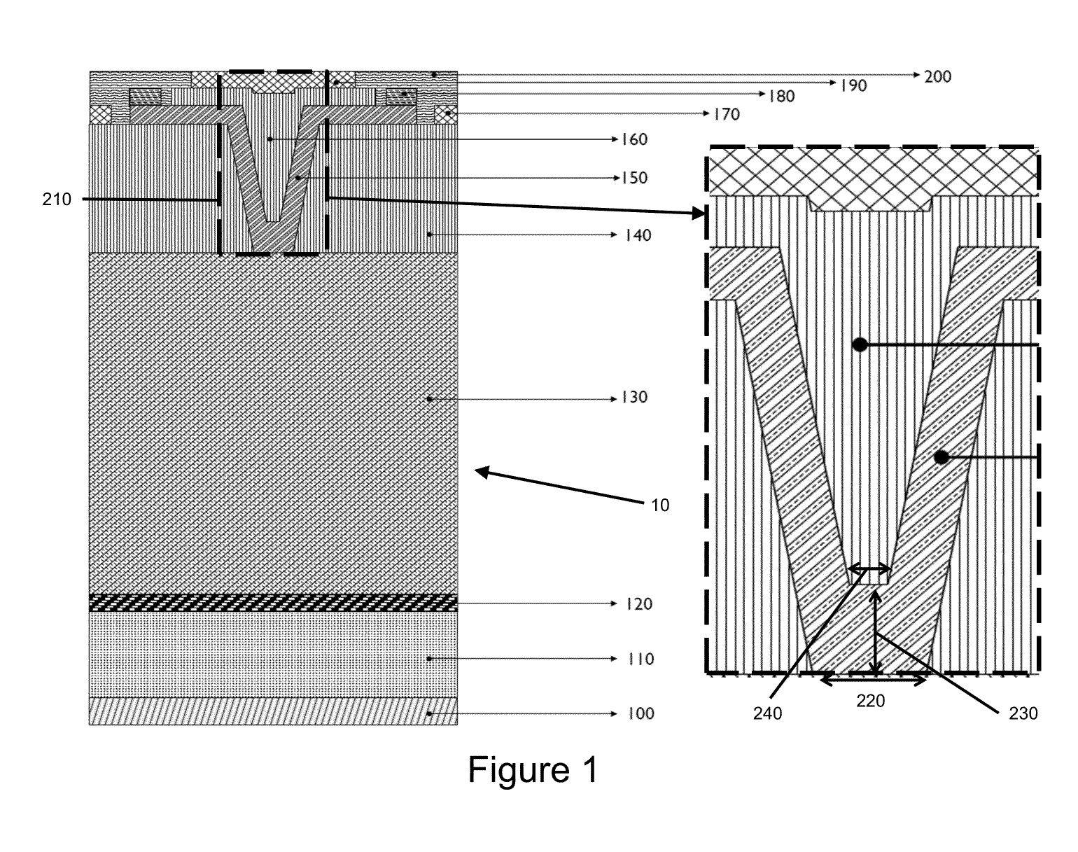

FIG. 1 illustrates a structure of a SAGBC-FET in accordance with some embodiments. The SAGBC-FET 10 includes a substrate 110, a buffer layer 120, a diffuse layer 130, a field layer 140, a channel layer 150, a gate structure 160, a field gate 170, a source electrode 180, a gate electrode 190, a passivation layer 200, and a drain electrode 100. The field layer 140 can include a trench that exposes the diffuse layer 130 to the channel layer 150 so that the diffuse layer 130 can come into contact with the channel layer 150. In this vertical SAGBC-FET 10, a current can flow from the drain electrode 100 to the source electrode 180 via the diffuse layer 130 and the channel layer 150. The current through the channel layer 150 can be cut off by controlling a width of a depletion region between the channel layer 150 and the gate structure 160. The width of the depletion region can be controlled with a potential applied to the gate structure 160 via the gate electrode 190.

In some embodiments, the channel layer 150 can form a depletion region with the field layer 140. The width of the depletion region between the channel layer 150 and the field layer 140 can be controlled with a potential applied to the field layer 140 via the field gate 170. This additional control of the depletion region can provide a more stable current control via the channel layer 150.

In some embodiments, the SAGBC-FET 10 can include one or more layers of wide band gap materials, such as SiC, AlN, GaN and/or ZnO based compounds. The wide band gap materials can allow a transistor device to sustain a high electric field (e.g., a high critical field.)

In some embodiments, the SAGBC-FET 10 can include a substrate 110 formed using wide band gap materials, such as SiC, AlN, GaN and/or ZnO based compounds. Due to a potentially low lattice mismatch between the substrate 110 and epitaxial layers 120/130, such a substrate 110 can enable the growth of low defect density monocrystalline epitaxial layers including ZnO-based epitaxial layers, and or AlₓGa₁₋ₓN and or InₓGa₁₋ₓN where 0≦x≦1. The low defect density monocrystalline epitaxial layers can provide an efficient device performance. In some embodiments, the substrate 110 can be optically transparent and, if desired, doped so as to be electrically conductive or compensated.

In some embodiments, the substrate 110 may include a crystal having a predetermined crystal orientation. For example, the substrate 110 can include one of the following crystal orientations: (000±1) c-plane polar materials; (10±10) m-plane non-polar materials; (11±20) a-plane non-polar materials; or (10-1±1), (20-2±1), (10-1±2), (11-2±1), (11-2±2) semi polar materials. Such a substrate 110 can provide a low-cost and large surface area (greater than about one-inch diameter) substrate and thus facilitate the production of cost effective and efficient power transistor devices.

In some embodiments, the SAGBC-FET 10 can also include a buffer layer 120 formed on top of the substrate 110. The buffer layer 120 can serve as an interface between a substrate 110 and a diffuse layer 130 such that the diffuse layer 130 can be monocrystalline. The buffer layer 120 can include one or more semiconductor layers. In some cases, the buffer layer 120 can be formed using ZnO based materials. For example, the buffer layer 120 can be formed using ZnₓMg₁₋ₓO and/or ZnₓCo₁₋ₓO, where 0≦x≦1. In other cases, the buffer layer 120 can be formed using GaN based materials. For example, the buffer layer 120 can be formed using AlₓGa₁₋ₓN based materials, where 0≦x≦1.

In some embodiments, the SAGBC-FET 10 can include a diffuse layer 130 formed on top of the buffer layer 120. The diffuse layer 130 can include one or more epilayers—layers of semiconducting materials formed using an epitaxial process. The one or more epilayers can include one or more n-type and p-type doped epilayers. In some embodiments, the epilayers can be formed using wide band gap materials. For example, the diffuse layer 130 can include ZnₓMg₁₋ₓO and or AlₓGa₁₋ₓN with 0≦x≦1. In some embodiments, the epilayers can have a thickness ranging between about 3 μm to about 300 μm, and preferably between about 10 μm and about 150 μm. In some embodiments, the epilayers can include monocrystalline layers (e.g., single crystal layers.) As described further herein, epilayers can be formed by depositing a layer of materials on top of another layer of materials.

In some embodiments, the SAGBC-FET 10 can include a field layer 140 formed on top of the diffuse layer 130. The field layer 140 can include epilayers doped in a particular polarity e.g. p-type or n-type. In some cases, the field layer 140 can be recessed from the surface or within the bulk of the diffuse layer 130. The field layer 140 can include a trench 210 for exposing the diffuse layer 130. The trench 210 can be formed using a photolithographic process and an etching process. The etching process can include wet etching, inductively coupled plasma-reactive ion etching (ICP-RIE), and/or reactive ion etching (RIE). In some embodiments, a width 220 of the trench 210 can be substantially larger compared to a minimum feature size of a lithographic process. For example, the width 220 can be within a range of 0.1 μm to 100 μm in a 22 nm lithographic process. The width 220 of the trench 210 does not limit a minimum feature size of the gate region or the channel width, as discussed below.

In some embodiments, the SAGBC-FET 10 can include a channel layer 150 formed on top of the field layer 140. The channel layer 150 can include one or more epilayers having an opposite polarity compared to the field layer 140. For example, if the field layer 140 is a p-type layer, then the channel layer 150 can be an n-type layer; if the field layer 140 is a n-type layer, then the channel layer 150 can be a p-type layer.

In some embodiments, the thickness 230 of the channel layer 150 can determine a switching characteristic of the SAGBC-FET 10. For example, when the thickness 230 is large, then the amount of current flowing through the channel layer 150 across its thickness (e.g., vertically) during the “on” state (or the maximum current flowing through the channel layer 150) can be correspondingly large. However, it would be correspondingly challenging to turn off the SAGBC-FET 10. In order to turn off a wide channel layer 150, a large enough potential needs to be applied to the gate structure 160 so that a depletion region large enough to cut-off the wide channel layer 150 is created. In contrast, when the thickness 230 is small, then the amount of current flowing through the channel layer 150 across its thickness (e.g., vertically) during the “on” state (or the maximum current flowing through the channel layer 150) can be correspondingly small. However, it would be correspondingly easier to turn off the SAGBC-FET 10. In this case, in order to turn off a thin channel layer 150, a small potential applied to the gate structure 160 would be sufficient to create a large-enough depletion region that would cut-off the thin channel layer 150. Therefore, controlling the thickness 230 of the channel layer 150 can be important.

The thickness 230 of the channel layer 150 can be controlled by controlling the epitaxial process. Therefore, the thickness 230 of the channel layer 150 can be controlled up to a precision level of the epitaxial process, which can be very high. In some embodiments, the thickness 230 of the channel layer 150 can be controlled by controlling the amount of time during which the channel layer material is deposited onto the field layer 140. If the channel layer material is deposited for a short period of time, then the thickness 230 of the channel layer 150 would be correspondingly small; if the channel layer material is deposited for a long period of time, then the thickness 230 of the channel layer 150 would be correspondingly large. In some embodiments, the thickness 230 of the channel layer 150 can also be controlled by controlling a concentration of the channel layer material during the deposition process.

The SAGBC-FET 10 can also include a gate structure 160. The gate structure 160 can be deposited on top of the channel layer 150. Unlike conventional transistor devices, the gate structure 160 need not be defined using a lithographic process; the gate structure 160 can be formed using an epitaxial process, just as the channel layer 150 can be formed using an epitaxial process. Thus, the SAGBC-FET 10 does not require a lithographic process step for providing the gate structure 160. Furthermore, because the gate structure 160 can be formed using the same epitaxial process as the channel layer 150, the likelihood of injecting impurities at an interface between the gate structure 160 and the channel layer 150 can be substantially reduced compared to a conventional gate formation process using a lithographic technique. The epitaxial process can include a metalorganic chemical vapor deposition (MOCVD) process. In some embodiments, the gate structure 160 can include semiconducting epilayers with thicknesses varying between about 0.01 μm to about 5 μm. The gate structure 160 can have an identical polarity to the diffuse layer 130 and an opposite polarity to the field layer 140.

In some embodiments, a portion of the gate structure 160 can reside in the trench 210. Since the gate structure 160 is formed in the same trench 210 as the channel layer 150, the gate structure 160 is “self-aligned” with the channel layer 150.

Unlike a conventional transistor whose minimum gate structure size is determined by a resolution of a lithographic process, the minimum gate structure size in the SAGBC-FET 10 is not limited by a resolution of a lithographic process since the gate structure 160 can be formed without using a lithographic process. Instead, the size of the minimum feature in the gate structure 160, also referred to as a gate pitch 240, is determined by the width 220 of the trench 210 and/or the thickness 230 of the channel layer 150. For example, if the width 220 of the trench 210 is a minimum feature size of a lithographic process, e.g., 22 nm, the gate pitch 240 can be significantly smaller than the minimum feature size of the lithographic process, as illustrated in FIG. 1. Because the thickness 230 of the channel layer 150 can be accurately controlled, the gate pitch 240 can be accurately controlled as well.

In some embodiments, the SAGBC-FET 10 can include a field gate 170 that is electrically connected to the field layer 140. In some embodiments, the SAGBC-FET 10 can include a source electrode 180 that is electrically connected to the channel layer 150. In some embodiments, the SAGBC-FET 10 can include a gate electrode 190 that is electrically connected to the gate structure 160. In some embodiments, the SAGBC-FET 10 can include a passivation layer 200. The passivation layer 200 can include an oxide, nitride, oxynitride and/or a halogenated polymer. The passivation layer 200 can be formed around the electrodes. In some embodiments, a drain electrode 100 can be formed on a second side of the substrate 110 (e.g., a side of the substrate 110 that is opposite from the buffering layer 120.)

In some embodiments, layer 110 can be doped n-type. In some embodiments, layer 110 may comprise of n-type impurities between 10¹⁴ cm⁻³ to 10²¹ cm⁻³. In some embodiments, layer 110 may possess n-type resistivity from 1 Ω-cm to 10⁻⁶ Ω-cm.

In some embodiments, layer 110 can be doped p-type. In some embodiments, layer 110 may comprise of p-type impurities between 10¹⁴ cm⁻³ to 10²¹ cm⁻³. In some embodiments, layer 110 may possess p-type resistivity from 10³ Ω-cm to 10⁻⁴ Ω-cm.

In some embodiments, layer 120 can be doped n-type. In some embodiments, layer 120 may comprise of n-type dopants between 10¹⁴ cm⁻³ to 10²¹ cm⁻³. In some embodiments, layer 120 may possess n-type resistivity from 1 Ω-cm to 10⁻³ Ω-cm.

In some embodiments, layer 120 can be doped p-type. In some embodiments, layer 20 may comprise of p-type dopants between 10¹⁴ cm⁻³ to 10²¹ cm⁻³. In some embodiments, layer 120 may possess p-type resistivity from 10³ Ω-cm to 10⁻³ Ω-cm.

In some embodiments, layer 130 can be undoped, compensated or intrinsic. In some embodiments, layer 130 can be doped n-type. In some embodiments, layer 30 may comprise of n-type impurities between 10¹⁴ cm⁻³ to 10²¹ cm⁻³. In some embodiments, layer 130 may comprise of p-type impurities between 10¹⁴ cm⁻³ to 10²¹ cm⁻³. In some embodiments, layer 130 may possess n-type resistivity from 100 Ω-cm to 10⁻⁶ Ω-cm. In some embodiments, layer 130 may possess P-type resistivity from 10³ Ω-cm to 10⁻⁴ Ω-cm.

In some embodiments, layer 140 and layer 160 may possess n-type resistivity from 100 Ω-cm to 10⁻⁶ Ω-cm. In some embodiments, layer 140 and layer 160 may possess p-type resistivity from 1000 Ω-cm to 10⁻⁶ Ω-cm.

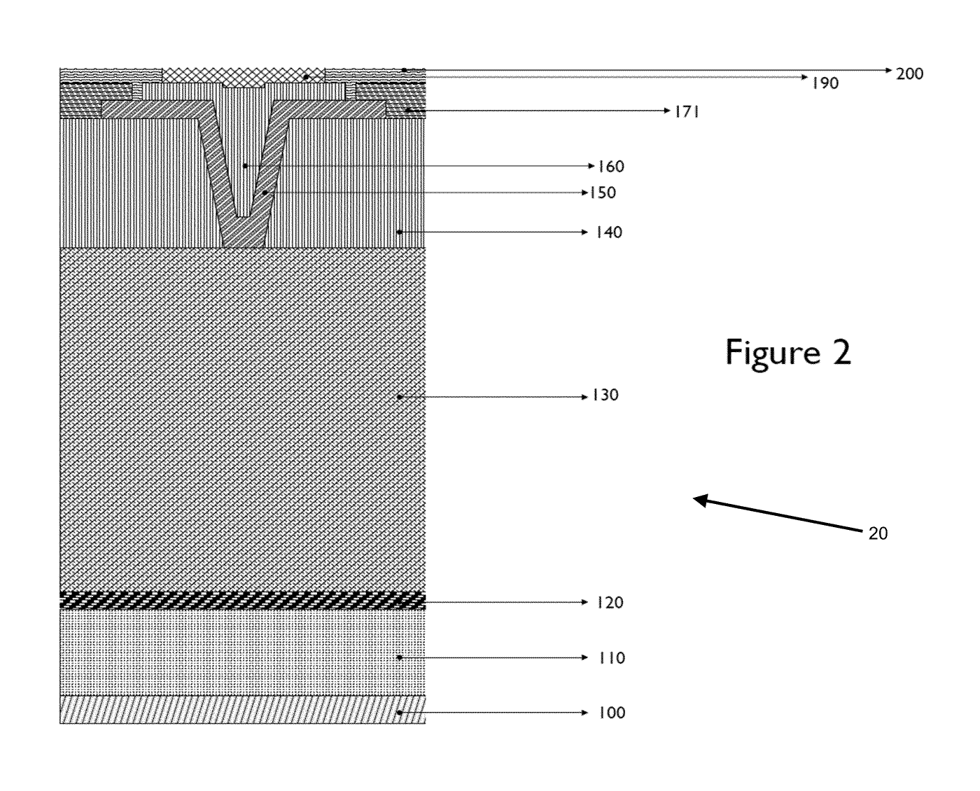

FIG. 2 illustrates a SAGBC-FET in series with a body-diode in accordance with some embodiments. The SAGBC-FET 20 includes a substantially similar structure as the SAGBC-FET 10. The SAGBC-FET 20 can additionally include a body diode that is formed by shorting the field gate 170 and the source electrode 180 using a joint electrode 171. Because the channel layer 150 and the field layer 140 have opposite polarities, a depletion region is formed at the interface between the channel layer 150 and the field layer 140. By shorting the field gate 170 and the source electrode 180, a body diode is formed between the channel layer 150 and the field layer 140.

The SAGBC-FET having an embedded body diode can be useful in power converter applications. A power converter system can include one or more power transistors, a capacitor, and/or an inductor to either boost an input voltage (e.g., a voltage from a battery) or to reduce the input voltage. In particular, the power converter system can use a power transistor to switch on or off a connection between the input voltage and an inductor. However, when the power transistor is turned off, a current flowing through the inductor can create an arc (e.g., an electric spark) which can degrade the power transistor as well as other components in the same power converter system. Oftentimes, a power converter system resolves this issue by including a diode in series with the power transistor. However, a separate diode in series with the power transistor can add an area and/or volume to the power converter system, and can further reduce a power conversion efficiency of the power converter system due to parasitic components associated with the separate diode.

The SAGBC-FET can address issues associated with a separate diode by directly embodying a body diode that is in series with the transistor in a single, monolithic structure. Because the SAGBC-FET already embodies a body diode, a power converter system does not need to separately connect the SAGBC-FET in series with another diode. Therefore, the SAGBC-FET can reduce an area/volume of the power converter system and also improve the power conversion efficiency of the power converter system.

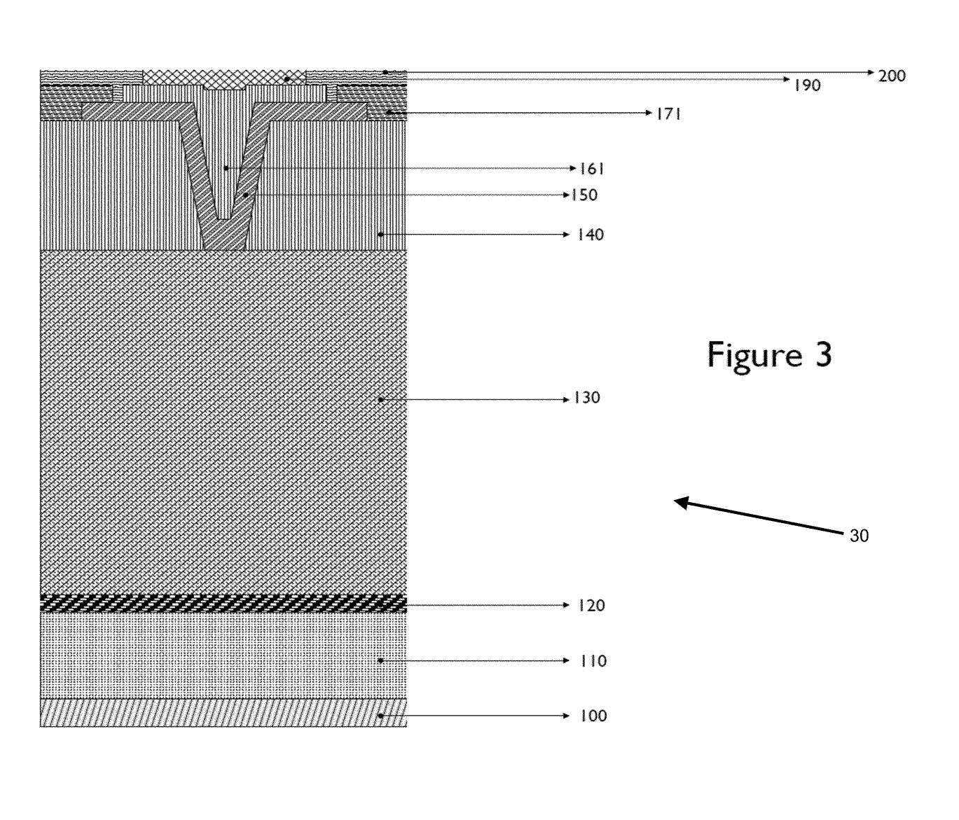

FIG. 3 shows a cross-sectional view of a SAGBC-FET having a dielectric gate structure in accordance with some embodiments. The SAGBC-FET 30 can include a substantially similar structure as the SAGBC-FET 10. However, instead of a gate structure 160 formed using one or more semiconducting materials, the SAGBC-FET 30 can include a dielectric gate structure 161. The dielectric gate structure 161 can include an oxide and/or nitride. For example, the dielectric gate structure 161 can include Al₂O₃, SiO/SiO₂, HfO, AlON, and/or SiₓN_{y}. A potential applied to the dielectric gate structure 161 via the gate electrode 190 can attract electrons on one side of the channel layer 150, thereby creating a conduit for transfer of electric charges. Thus, the operation of the SAGBC-FET 30 can be similar to an operation of a metal-oxide-semiconductor field-effect transistor (MOSFET). In some embodiments, the SAGBC-FET 30 can include a joint electrode 171 that shorts the field layer 140 and the channel layer 150 to form a body diode, as discussed with respect to FIG. 2.

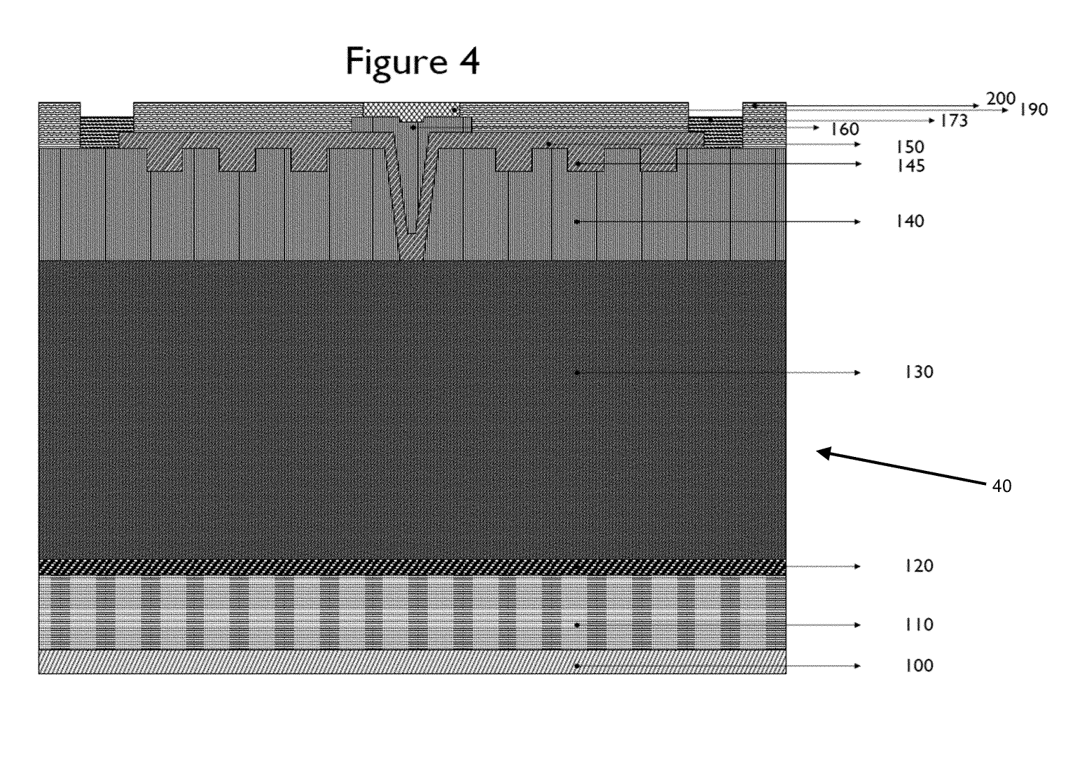

FIG. 4 shows a cross-sectional view of a SAGBC-FET having recesses in accordance with some embodiments. The structure of the SAGBC-FET 40 can be substantially similar to a structure of the SAGBC-FET 20. For example, the SAGBC-FET 40 includes a joint electrode that electrically connects the channel layer 150 and the field layer 140. However, the SAGBC-FET 40 can also include one or more satellite recesses 145 coupled to the channel layer 140. The satellite recesses can form additional body diodes between the satellite recesses 145 and the field layer 140. The additional surface area between the satellite recesses 145 and the field layer 140 can provide a larger body diode than the SAGBC-FET 20, thereby providing a more stable reduction of an electric arc in a power converter system. The satellite recesses 145 can be a part of the channel layer 150 (e.g., deposited at the same time as the channel layer 150). The trenches for the satellite recesses 145 can be formed using a lithographic process that is used to define the trench 210.

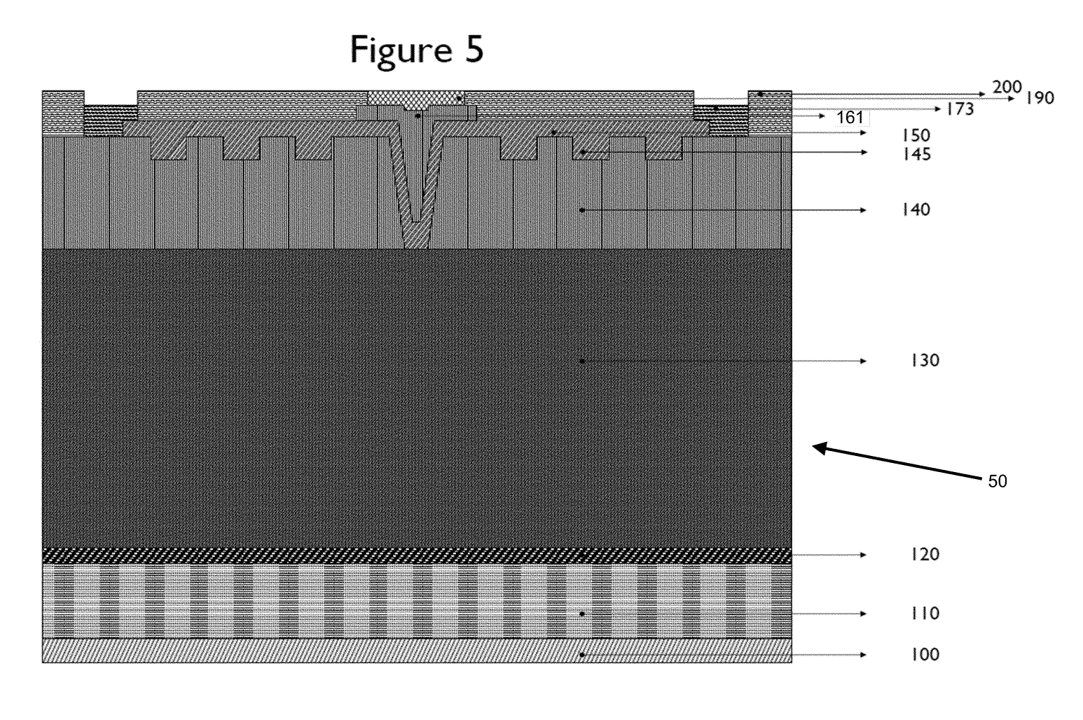

FIG. 5 shows a cross-sectional view of a SAGBC-FET having recesses and a dielectric gate structure in accordance with some embodiments. The structure of the SAGBC-FET 50 is substantially similar to the SAGBC-FET 40. However, instead of a gate structure 160 formed using one or more semiconducting materials, the SAGBC-FET 50 can include a dielectric gate structure 161. The dielectric gate structure 161 can include an oxide and/or nitride. For example, the dielectric gate structure 161 can include Al₂O₃, SiO/SiO₂, HfO, AlON, and/or SiₓN_{y}, as discussed with respect to FIG. 3.

In some embodiments, the field gate 170 and the gate electrode 190 can be formed using a material selected from a group comprising of metals or metal stacks including Cr, and or NiO and or Ni/Al/Au, Ni/Ti/Au, Pt/Au, Pt, Au, Ag or any combination of the foregoing to form electrical contact to the underlying semiconductor layers.

In some embodiments, a joint electrode 171, 173 and a source electrode 180 can be formed using a material selected from a group comprising of metals or metal stacks including Ti/Au, Ti/Al, Ti/Al/Au, Ti/Ni/Au, Ti/Al/Pt/Au, Cr/Au, Cr/Al, Cr/Al/Au, Al/Au, Al, Al/Pt, In, Ru Cr, or any combination of the foregoing to form electrical contact to the underlying semiconductor layers.

As used herein, when a structure (e.g., layer, region) is referred to as being “on”, “over” “overlying” or “supported by” another structure, it can be directly on the structure, or an intervening structure (e.g., layer, region) also can be present. A structure that is “directly on” or “in contact with” another structure means that no intervening structure is present. A structure that is “directly under” another structure means that no intervening structure is present.

The terms “an embodiment”, “embodiment”, “embodiments”, “the embodiment”, “the embodiments”, “an embodiment”, “some embodiments”, and “one embodiment” mean “one or more (but not all) embodiments of the present invention(s)” unless expressly specified otherwise.

The terms “including”, “having,” “comprising” and variations thereof mean “including but not limited to”, unless expressly specified otherwise.

The term “consisting of” and variations thereof mean “including and limited to”, unless expressly specified otherwise.

The enumerated listing of items does not imply that any or all of the items are mutually exclusive. The enumerated listing of items does not imply that any or all of the items are collectively exhaustive of anything, unless expressly specified otherwise. The enumerated listing of items does not imply that the items are ordered in any manner according to the order in which they are enumerated.

The terms “a”, “an” and “the” mean “one or more”, unless expressly specified otherwise.

Headings of sections provided in this patent application and the title of this patent application are for convenience only, and are not to be taken as limiting the disclosure in any way.

Having thus described several aspects of at least one embodiment of this invention, it is to be appreciated various alterations, modifications, and improvements will readily occur to those skilled in the art. Such alterations, modifications, and improvements are intended to be part of this disclosure, and are intended to be within the spirit and scope of the invention. Accordingly, the foregoing description and drawings are by way of example only.

We claim:

1. A vertical transistor comprising:
a substrate;
a first semiconducting layer disposed above a first side of the substrate;
a second semiconducting layer disposed above the first semiconducting layer, wherein the second semiconducting layer comprises a trench that exposes the first semiconducting layer;
a channel layer disposed within the trench, wherein the channel layer is in direct contact with the first semiconducting layer exposed by the trench;
a gate structure disposed above the channel layer, wherein the gate structure is partially disposed within the trench, and a width of a depletion region between the channel layer and the first semiconducting layer is controllable by a voltage applied to the gate structure; and
a source electrode, a gate electrode coupled to the gate structure, and a drain electrode.

2. The vertical transistor of claim 1, wherein the substrate comprises a ZnO-based material.

3. The vertical transistor of claim 1, wherein the channel layer comprises a first dopant having an opposite polarity compared to that of a second dopant in the second semiconducting layer.

4. The vertical transistor of claim 1, wherein a thickness of the channel layer is predetermined to control a maximum current that can be provided by the transistor.

5. The vertical transistor of claim 1, wherein the channel layer and the gate structure are formed in two consecutive, identical epitaxial process steps.

6. The vertical transistor of claim 5, wherein the epitaxial process comprises one of a metal-organic chemical vapor deposition (MOCVD) process, a molecular beam epitaxy (MBE) process, an atomic layer deposition (ALD) process, a hydride vapor phase epitaxy (HVPE) process, a chemical vapor transport (CVT) process, or a liquid phase epitaxy (LPE) process.

7. The vertical transistor of claim 1, wherein a pitch of the gate structure is determined by a thickness of the channel layer.

8. The vertical transistor of claim 7, wherein the pitch of the gate structure is further determined by a width of the trench in the second semiconducting layer.

9. The vertical transistor of claim 1, wherein a pitch of the gate structure is smaller than a minimum feature size of a lithographic process used to form the trench in the second semiconducting layer.

10. The vertical transistor of claim 1, wherein the first semiconducting layer comprises AlₓGa₁₋ₓN and/or ZnₓMg₁₋ₓO materials, wherein 0<x<1.

11. The vertical transistor of claim 10, wherein a thickness of the first semiconducting layer is within a range of about 3 μm and about 300 μm.

12. The vertical transistor of claim 1, further comprising a field gate electrically coupled to the second semiconducting layer, and wherein a width of a depletion region between the channel layer and the second semiconducting layer is designed to be controlled by a voltage applied to the field gate.

13. The vertical transistor of claim 12, wherein the source electrode and the field gate are electrically coupled, thereby forming a body diode in series with the vertical transistor.

14. The vertical transistor of claim 1, wherein the gate structure comprises a semiconducting material having an identical polarity as that of the first semiconducting layer and an opposite polarity as that of the second semiconducting layer.

15. The vertical transistor of claim 1, wherein the gate structure comprises a dielectric.

16. The vertical transistor of claim 1, further comprising a recess coupled to the channel layer, forming a body diode between the recess and the second semiconducting layer.

17. The vertical transistor of claim 1, wherein the substrate comprises a material having a crystal orientation selected from the group consisting of (000±1) c-plane polar materials, (10±10) m-plane non-polar materials, (11±20) a-plane non-polar materials, and (10-1±1), (20-2±1), (10-1±2), (11-2±1), (11-2±2) semipolar materials.

18. A method of providing a transistor, the method comprising:
providing a substrate;
providing a first semiconducting layer on a first side of the substrate;
depositing a second semiconducting layer on the first semiconducting layer;
providing a trench in the second semiconducting layer to expose a portion of the first semiconducting layer;
depositing a channel layer on the second semiconducting layer and the exposed portion of the first semiconducting layer, thereby providing a direct contact between the channel layer and the first semiconducting layer in the trench;
depositing a gate structure on the channel layer, wherein a portion of the gate structure is formed in the trench;
providing a source electrode, a gate electrode coupled to the gate structure, and a drain electrode.

19. The method of claim 18, further comprising providing a buffer layer between the first semiconducting layer and the substrate to facilitate a formation of the first semiconducting layer.

20. The method of claim 18, further comprising controlling an amount of time for depositing a semiconducting material for the channel layer, thereby controlling a thickness of the channel layer.

21. The method of claim 18, further comprising controlling a concentration of a semiconducting material for the channel layer during the deposition of the channel layer to control a thickness of the channel layer.

22. The method of claim 18, wherein providing the trench in the second semiconducting layer comprises using a lithographic technique to form the trench in the second semiconducting layer.

23. The method of claim 18, wherein the channel layer and the gate structure are deposited in two consecutive, identical epitaxial process steps.

24. The method of claim 23, wherein the epitaxial process comprises one of a metal-organic chemical vapor deposition (MOCVD) process, a molecular beam epitaxy (MBE) process, an atomic layer deposition (ALD) process, a hydride vapor phase epitaxy (HVPE) process, a chemical vapor transport (CVT) process, or a liquid phase epitaxy (LPE) process.

25. The method of claim 18, wherein the channel layer comprises a first dopant having an opposite polarity compared to that of a second dopant in the second semiconducting layer.

26. The method of claim 18, wherein a thickness of the first semiconducting layer is within a range of about 3 μm and about 300 μm.
